(19) United States
(12) Patent Application Publication
(10) Pub. No.: US 2020/0381209 A1
(43) Pub. Date: Dec. 3, 2020

(54) CHARGE STRIPPING FOR ION IMPLANTATION SYSTEMS

(71) Applicant: Axcelis Technologies, Inc., Beverly, MA (US)

(72) Inventor: Shu Satoh, Byfield, MA (US)

(21) Appl. No.: 16/887,446

(22) Filed: May 29, 2020

Related U.S. Application Data
(60) Provisional application No. 62/853,945, filed on May 29, 2019.

(51) Int. Cl. H01J 37/317; H01J 37/08; H01J 37/32

(52) U.S. Cl. CPC H01J 37/3171; H01J 37/08; H01J 2237/05; H01J 2237/0048; H01J 2237/04737; H01J 37/3244

(57) ABSTRACT

An ion implantation system has a source that generates ions from a beam species to form an ion beam, and a mass analyzer mass analyzes the ion beam. An accelerator receives the ion beam having ions at a first charge state and exits the ion beam having ions at a second positive charge state. The accelerator has a charge stripper, a gas source, and a plurality of accelerator stages. The charge stripper converts the ions from the first charge state to the second charge state. The gas source provides a high molecular weight gas, such as hexafluoride, to the charge stripper, and the plurality of accelerator stages respectively accelerate the ions. An end station supports a workpiece to be implanted with ions at the second charge state.

### REFERENCE TO RELATED APPLICATIONS

This application claims the benefit of U.S. Provisional Application No. 62/853,945 filed May 29, 2019, entitled “IMPROVED CHARGE STRIPPING FOR ION IMPLANTATION SYSTEMS”, the contents of which are herein incorporated by reference in their entirety.

### TECHNICAL FIELD

The present disclosure relates generally to ion implantation systems, and more particularly to a system and method for increasing beam current available at a maximum energy for a charge state without using a higher charge state at an ion source.

### BACKGROUND

In the manufacture of semiconductor devices, ion implantation is used to dope semiconductors with impurities. Ion implantation systems are often utilized to dope a workpiece, such as a semiconductor wafer, with ions from an ion beam, in order to either produce n- or p-type material doping, or to form passivation layers during fabrication of an integrated circuit. Such beam treatment is often used to selectively implant the wafers with impurities of a specified dopant material, at a predetermined energy level, and in controlled concentration, to produce a semiconductor material during fabrication of an integrated circuit. When used for doping semiconductor wafers, the ion implantation system injects a selected ion species into the workpiece to produce the desired extrinsic material. Implanting ions generated from source materials such as antimony, arsenic, or phosphorus, for example, results in an “n-type” extrinsic material wafer, whereas a “p-type” extrinsic material wafer often results from ions generated with source materials such as boron, gallium, or indium.

A typical ion implanter includes an ion source, an ion extraction device, a mass analysis device, a beam transport device and a wafer processing device. The ion source generates ions of desired atomic or molecular dopant species. These ions are extracted from the source by an extraction system, typically a set of electrodes, which energize and direct the flow of ions from the source, forming an ion beam. Desired ions are separated from the ion beam in a mass analysis device, typically a magnetic dipole performing mass dispersion or separation of the extracted ion beam. The beam transport device, typically a vacuum system containing a series of focusing devices, transports the ion beam to the wafer processing device while maintaining desired properties of the ion beam. Finally, semiconductor wafers are transferred in to and out of the wafer processing device via a wafer handling system, which may include one or more robotic arms, for placing a wafer to be treated in front of the ion beam and removing treated wafers from the ion implanter.

### SUMMARY

The present disclosure provides various ion implantation apparatuses, systems, and methods for increasing beam current available at a maximum energy for a charge state without using a higher charge state at an ion source. Accordingly, the following presents a simplified summary of the disclosure in order to provide a basic understanding of some aspects of the disclosure. This summary is not an extensive overview of the disclosure. It is intended to neither identify key or critical elements of the invention nor delineate the scope of the invention. Its purpose is to present some concepts of the invention in a simplified form as a prelude to the more detailed description that is presented later.

In accordance with one example of the present disclosure, an ion implantation system is provided, wherein an ion source is configured to generate an ion beam from a beam species, therein defining a generated ion beam. A mass analyzer, for example, is configured to mass analyze the generated ion beam to define an analyzed ion beam, wherein the analyzed ion beam comprises ions (e.g., positive or negative ions) of the beam species at a first charge state.

An accelerator, for example, is further provided and configured to receive the analyzed ion beam. The accelerator is further configured to define an exited ion beam, wherein the exited ion beam comprises positive ions of the beam species at a second charge state. The accelerator, for example, comprises a charge stripper configured to receive the positive or negative ions of the beam species at the first charge state at a location within the accelerator, wherein the charge stripper is configured to convert ions of the first charge state to the positive ions of the beam species at the second charge state. A gas source is further provided and configured to provide a high molecular weight gas to the charge stripper. Further, an accelerator stage is provided and respectively configured to accelerate the positive ions. Finally, an end station is positioned downstream of the accelerator and configured to support a workpiece that is to be implanted with the ions of the exited ion beam comprising the second charge state.

According to one aspect of the disclosure, the high molecular weight gas comprises sulfur hexafluoride gas. In accordance with another aspect, the charge stripper comprises a supply of a gas for stripping electrons from the ions and a control device configured to adjust a flow rate of the gas into the charge stripper of the accelerator based on at least one of energy, current and species of the ion beam. The gas, for example, may comprise the high molecular weight gas.

In one example, the accelerator comprises a well-known “tandem accelerator” in which a negative ions at the first charge state are accelerated toward a positive terminal where they are charge-stripped to become positive ions at the second charge state in order to gain another cycle of acceleration toward the ground potential at the exit, thereof.

The second charge state, for example, comprises a more positive charge state than the first charge state. Further, the beam species, for example, can comprise one or more of boron and phosphorus.

The charge stripper, in another example, is provided at location along a path of the ion beam where more positive ions of the second positive charge state are present than positive ions that are available at the ion source. The charge stripper is further configured to increase a beam current of the ion beam to an energy range that is higher than otherwise obtained with positive ions of the first charge state. The charge stripper, for example, is provided downstream of at least one of a first plurality of accelerator stages of the accelerator in a direction of the ion beam, and upstream of at least one of a second plurality of accelerator stages of the accelerator.

In one example, the second charge state increases a net charge of the first charge state by at least one. In another example, the high molecular weight gas provided by the gas source comprises sulfur hexafluoride, wherein the first charge state comprises a net charge of +3 and the second charge state comprises a net charge of +6.

In accordance with another example, the present disclosure provides a method of operating a high energy ion implanter, wherein an ion beam of a beam species is generated from an ion source. The ion beam is mass analyzed, and ions of a first charge state (e.g., a first positive charge state or a first negative charge state) are selectively passed into an accelerator. The ions of the first charge state are accelerated through at least one of a first plurality of accelerator stages located within the accelerator to attain a first kinetic energy level, thereby defining accelerated ions. The accelerated ions are then passed through a charge stripper within the accelerator, wherein the charge stripper comprises a high molecular weight gas such as sulfur hexafluoride. As such, the ions of the first charge state are converted to ions of a second (positive) charge state, wherein the first charge state is different from the second positive charge state and wherein stripping is performed with a stripping efficiency that is based upon the first kinetic energy level. As such, more ions of the second positive charge state are attained than originally present at the ion source, while a beam current and second energy of the ion beam is higher than the first kinetic energy level obtained with positive ions of the first charge state. The ions of the second positive charge state are then accelerated through at least one of a second plurality of accelerator stages located within the accelerator.

The above summary is merely intended to give a brief overview of some features of some embodiments of the present invention, and other embodiments may comprise additional and/or different features than the ones mentioned above. In particular, this summary is not to be construed to be limiting the scope of the present application. Thus, to the accomplishment of the foregoing and related ends, the invention comprises the features hereinafter described and particularly pointed out in the claims. The following description and the annexed drawings set forth in detail certain illustrative embodiments of the invention. These embodiments are indicative, however, of a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1 is a simplified top view illustrating an ion implantation system in accordance with an aspect of the present disclosure;

FIG. 2 is a portion of an ion implantation system according to at least one aspect of the present disclosure;

FIG. 3 illustrates a charge state distribution of an arsenic beam through argon and sulfur hexafluoride;

FIG. 4 illustrates various medium used in stripping charge;

FIG. 5 is a flow chart diagram illustrating a method of increasing beam current according to yet another embodiment of the present disclosure; and

FIG. 6 is a flow chart diagram illustrating a method of increasing beam current according to yet another embodiment of the present disclosure.

### DETAILED DESCRIPTION

Ion implantation is a physical process, as opposed to diffusion, which is a chemical process that is employed in semiconductor apparatus fabrication to selectively implant dopant into a semiconductor workpiece and/or wafer material. Thus, the act of implanting does not rely on a chemical interaction between a dopant and the semiconductor material. For ion implantation, dopant atoms/molecules are ionized and isolated, sometimes accelerated or decelerated, formed into a beam, and swept across a workpiece or wafer. The dopant ions physically bombard the workpiece, enter the surface and typically come to rest below the workpiece surface in the crystalline lattice structure thereof.

In RF-based accelerators and DC-based accelerators, ions can be repeatedly accelerated through multiple acceleration stages of an accelerator. For example, RF-based accelerators can have voltage driven acceleration gaps. Due to the time varying nature of RF acceleration fields and the multiple numbers of acceleration gaps there are a large number of parameters, which influence the final beam energy. Because the charge state distribution of an ion beam can change, substantial effort is paid to keep the charge value in the ion beam at the initially intended single value. However, greater demands for an implantation recipe (e.g., ion beam energy, mass, charge value, beam current and/or total dose level of the implantation) at a higher energy level call for providing a higher beam current without compromising the ion source unnecessarily. Accordingly, suitable systems or methods for increasing beam current are desired.

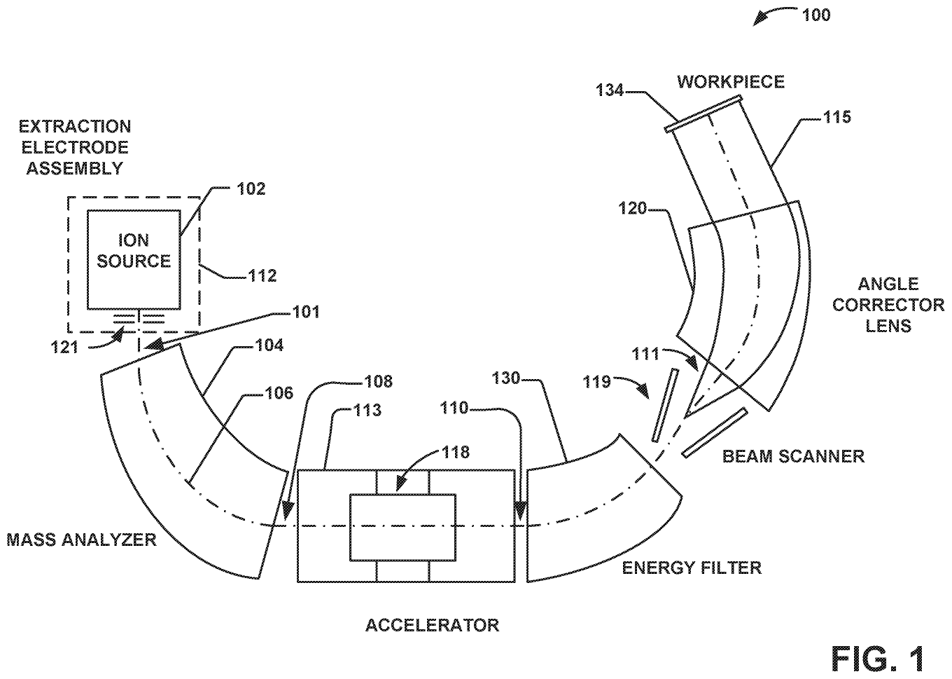

Referring now to the figures, in accordance with one exemplary aspect of the present disclosure, FIG. 1 illustrates a hybrid parallel scan single wafer ion implantation system 100. The implantation system 100 is also referred to as a post acceleration implanter, since a main accelerator 113 is placed after a mass analyzer 104 analyzing an ion beam 106 and before an energy filter 130. Ion implanters of this type often have the energy filter 130 after the accelerator 113 to remove unwanted energy spectrum in the output of accelerator 113. In one embodiment, an ion beam 101 generated from an ion source 102 may be accelerated by an accelerator in an acceleration stage (not shown) before the mass analyzer 104 to generate an accelerated and/or analyzed ion beam 108, for example. Downstream the accelerated and/or analyzed ion beam 108 may be accelerated again in the accelerator 113 by a plurality of accelerator stages therein. For example, the accelerator stages may comprise resonators (as with an RF accelerator) respectively to generate RF acceleration fields therein and output an exited ion beam 110 that has been further accelerated. After passing through the energy filter 130, the filtered ion beam goes through a beam scanner 119 and then through an angle corrector lens 120 to convert the fanned-out beam 111 into a parallel shifted ion beam 115.

A workpiece and/or substrate 134 is moved orthogonal (shown as moving in and out of the paper) to the ion beam 115 in the hybrid scan scheme to irradiate the entire surface of the workpiece 134 uniformly. As stated above, various aspects of the present disclosure may be implemented in association with any type of ion implantation system, including, but not limited to the exemplary system 100 of FIG. 1.

The exemplary hybrid parallel scan single wafer ion implantation system 100, for example, comprises a source chamber assembly 112, which comprises the ion source 102 and an extraction electrode assembly 121 to extract and accelerate ions to an intermediate energy. A mass analyzer 104 removes unwanted ion mass and charge species and the accelerator assembly 113 accelerates the ions to a final energy. The beam scanner 119 scans a beam exiting from the accelerator assembly 113 back and forth at a fast frequency into the angle corrector lens 120 to convert the fanning out scanned beam 111 from the beam scanner 119 to the parallel shifted beam 115 and the workpiece 134, which can be housed in a process chamber or end station (not shown).

The accelerator assembly 113, for example, can be an RF linear particle accelerator (LINAC) in which ions are accelerated repeatedly by an RF field, or a DC accelerator (e.g., a tandem electrostatic accelerator), which accelerates ions with a stationary DC high voltage. The beam scanner 119, either electrostatically or electromagnetically scans the ion beam 110 left to right into the angle corrector lens 120, which converts the fanning-out beam 111 into the parallel shifted ion beam 115. The angle corrector lens 120 can be an electromagnetic magnet as shown, but there is also an electrostatic version, for example. The final parallel shifted ion beam 115 out of the angle corrector lens 120 is directed onto the workpiece 134.

In one embodiment, the final kinetic energy of ion particles passing through the accelerator 113 can be increased by increasing the ion charge value (q). The ion charge state (q) can be increased in one embodiment by providing a charge stripper 118 within the accelerator 113 between first and second accelerator stages. For example, in an RF accelerator a number of accelerator stages (e.g., six or more) can comprise resonators for generating an accelerating field (not shown), and at least one of the accelerator stages can comprise a second accelerator stage after the charge stripper 118.

In one embodiment, acceleration of the ion beam can occur before the charge stripper 118 located within the accelerator 113, for example, through a first plurality of acceleration stages within the accelerator 113. Acceleration can also occur after the charger stripper 118, for example, through a second plurality of acceleration stages within the accelerator 113. Alternatively, the first plurality of acceleration stages may be external to the accelerator 113. For example, the first plurality of acceleration stages can be located before the mass analyzer, and thus, the ion beam 108 is both an accelerated and analyzed ion beam 108 entering the charge stripper 118.

In one embodiment, the ion beam 108 comprises positive ions comprising a first charge state (e.g., As 3⁺) where the net electrical charge of the ions can be positive. After entering the charge stripper 118, a fraction of the positive ions of the first charge state can be converted into positive ions of a second charge state (e.g., As 6⁺). In another embodiment utilizing a so-called tandem accelerator, the ion beam 108 comprises negative ions which are accelerated in the first stage of accelerator before stripper.

Accordingly, the ion beam 110 exiting the accelerator 113 comprises a lower concentration of the ions of the first charge state, a concentration of ions of the second charge state, and an increase in beam current that is above the kinetic maximum energy level available using the first charge state. For example, the ion beam can comprise any number of beam species, such as Arsenic, Boron, Phosphorus, or other species.

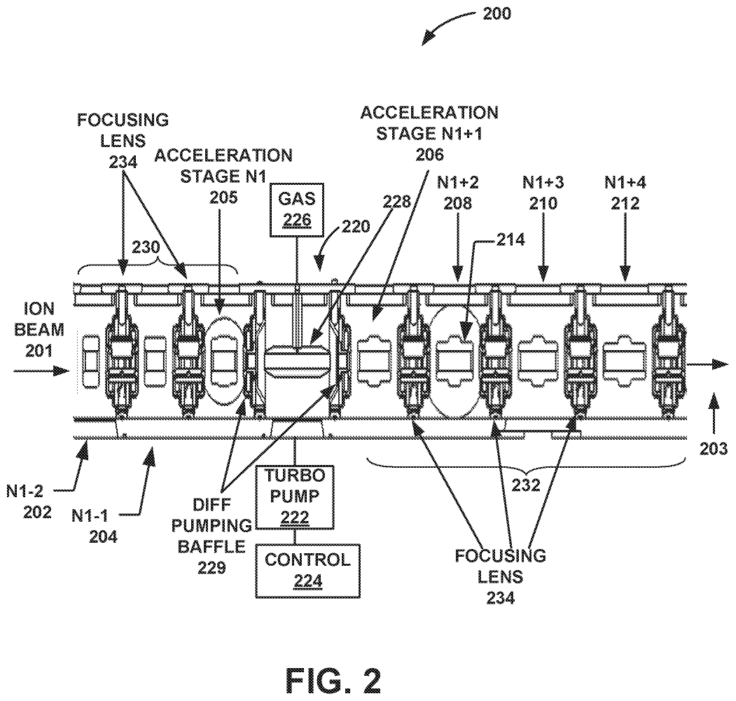

FIG. 2 illustrates one example of a portion of an ion implantation system in accordance with one aspect of the disclosure. An accelerator 200 can comprise at least one of a first plurality of accelerator stages 230, for example, and at least one of a second plurality of accelerator stages 232. For example, the accelerator 200 can comprise an RF accelerator, which is illustrated in FIG. 2 as one example of an embodiment, and can comprise any number of accelerator stages (e.g., 202, 204, 205, 206, 208, 210, and 212). The accelerator stages 202, 204, 205, 206, 208, 210, and 212 can respectively comprise at least one accelerator electrode 214 which is driven by an RF resonator, for example, for generating a RF accelerating field on both sides (not shown). An ion beam 201 of charged particles with a charge state (e.g., a net electrical charge or a valence) can pass through apertures of the accelerator electrode in succession. The principles of acceleration are well known in the art.

Beam focusing can be provided by lenses 234 (e.g., electrostatic quadrupole) incorporated within the accelerator 200. In one embodiment, the accelerator 200 can accelerate singly-charged ions to a maximum kinetic energy level for a first charge state. In one embodiment, ions of a higher second charge state can be employed to reach higher energy levels than the maximum kinetic energy level for a lower first charge state. Thus, the ion beam 201 comprising ions of the first charge state can enter the accelerator 200 as an entering beam and be converted to ions of a second charge state of a higher or lower net charge valence. By removing electrons therein, as by a charge stripper 220 incorporated within the accelerator 200, the entering beam 201 can be converted to an exiting beam 203 comprising ions of the second higher charge state (e.g., As 3+ converted to As 6+), thereby increasing beam energy beyond the maximum kinetic energy level for the first charge state.

Once the ion beam 201 has been extracted and formed, the beam 201 may be accelerated by the accelerator 200 (e.g., a 13.56 MHz twelve resonator RF linear accelerator). There is no one particular accelerator that the present disclosure is confined to. In one embodiment, the accelerator 200 can comprise a first plurality of accelerator stages 230 integrated in the accelerator 200 for accelerating the ion beam 201 therein and a second plurality of accelerator stages 232 integrated in the accelerator 200 for further acceleration of ions in the ion beam 203 therein. While the first plurality of accelerator stages are integrated in the accelerator 200 and upstream of the charge stripper 220 in the illustrated example of FIG. 2, the first plurality of accelerator stages 230 may be located before a mass analyzer (e.g., mass analyzer 104 of FIG. 1). Thus, the charge stripper 220 can be located at any of the acceleration stages of the accelerator 200 as long as the first plurality of accelerator stages provide enough energy to the ions of first charge state, high enough to guarantee a high stripping efficiency for the production of the second charge state, greater than the amount available at the ion source.

For example, resonators of an RF accelerator can be replaced at any acceleration stage with the charge stripper 220. In one embodiment, for example, the charge stripper 220 can be located downstream of at least one of the first plurality of accelerator stages 230 of the accelerator in a direction of the ion beam 201, and upstream of at least one of the second plurality of accelerator stages 232 of the accelerator 200. In other embodiments, for example, the first plurality of accelerator stages of the accelerator can comprise more or less accelerator stages than the second plurality of accelerator stages. Alternatively, the first plurality of accelerator stages of the accelerator can comprise an equal number of accelerator stages than the second plurality of accelerator stages. The number of stages is not confined to the illustration of FIG. 2.

In a further embodiment, the ion beam 201 entering the accelerator 200 comprises a positive or negative ion beam of the first charge state, and the exiting ion beam 203 comprises a positive ion beam of the second charge state that comprises a more positive charge state than the first charge state. The entering ion beam 201 can enter the charge stripper 220, for example, which comprises of a thin tube filled with a heavy molecular weight gas, such as SF₆, called a stripper tube 228. The charge stripper can also comprise a pump 222 (e.g., a differential turbo pump) for pumping a gas from a gas source 226 to reduce amount of stripper gas flow into adjacent accelerator section. The gas comprises sulfur hexafluoride (SF₆) or another high molecular weight gas for efficiently stripping electrons from the ion beam 201 and generating a higher concentration of ions within the ion beam 203 that comprise a higher positive charge state. The charge stripper and/or pump can comprise a control device 224 configured to adjust a flow rate of the gas from the gas source 226 into the charge stripper 220. The flow rate of the gas can be a functionally based on at least one of energy, current, and/or species of the ion beam 201. The charge stripper 220 can further comprise a pumping baffle 229 (e.g., a differential pumping baffle) on both sides of the charge stripper 220. The pumping baffle 228 can function to minimize a gas leak into adjacent accelerator stages (e.g., accelerator stages 205 and 206) together with the differential pump 222.

For example, an accelerated ion beam by a first linear accelerator (LINAC) is directed to a layer of gas configured to strip away electrons surrounding the ions in the charge stripper 220 order to increase the charge state of the ions to achieve a higher energy gain through a second LINAC. For example, for the top energy range of arsenic (As), 3+ arsenic ions that are accelerated through the first LINAC are stripped to 6+ arsenic ions by the charge stripper 220. As such, approximately 8% of the 7 MeV 3+ arsenic ions are converted to 6+ arsenic ions. However, if the conversion were to be more efficient, more 6+ beam current could be achieved.

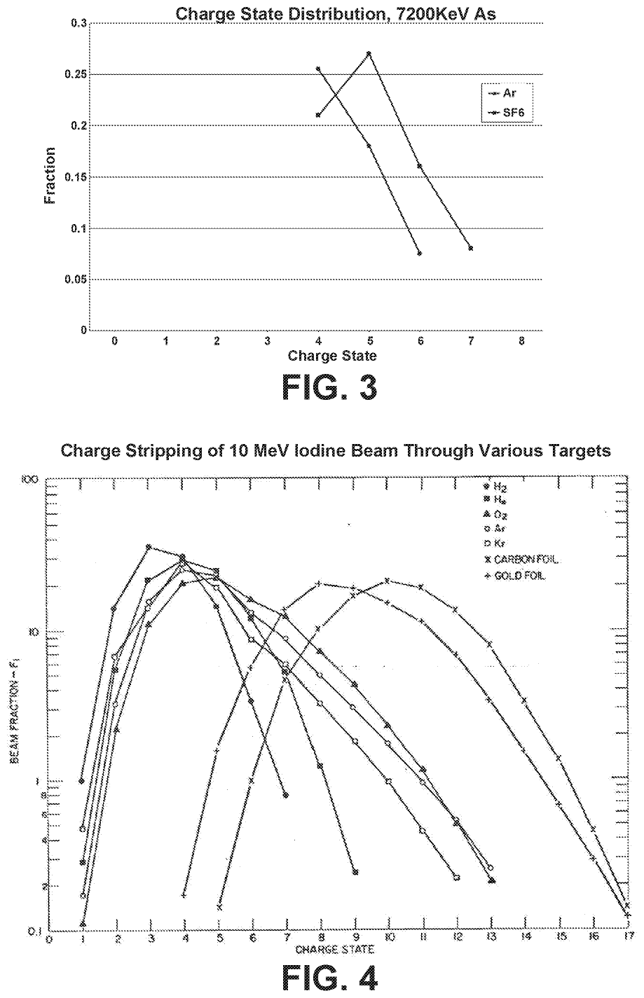

Tandem high energy accelerators generally rely on charge stripping to produce high energy ions, whereby such tandem high energy accelerators have conventionally utilized argon gas for such charge stripping. On so-called “ultra-high energy” tandem accelerators, extremely thin carbon foil has also been utilized as a charge stripper, but the short life time of the carbon foil has limited applicability in any industrial use of ion implantations and is presently known to be solely used on academic research accelerators. For example, charge stripping capabilities associated with passing a 10 MeV iodine ion beam through various gases and foils is provided for in FIG. 3.

Heretofore, stripping of ions has been generally limited to the gases such as those shown in FIG. 4, and primarily, to the utilization of argon gas. The present disclosure, however, has discovered that sulfur hexafluoride (SF₆) gas can be advantageously utilized for stripping arsenic ions in a gas stripper, whereby the charge state distribution tends to shift to higher charge states and therefore, the yield of the 6+ ions, for example, are almost twice that conventionally seen with argon gas.

The graph shown in FIG. 3 illustrates a comparison of the charge state distribution after passing a 7200 KeV arsenic ion beam through a gas stripper containing SF₆ and through a gas stripper containing argon. As is clearly shown, use of SF₆ doubles the 5+ and 6+ ion yields, thus increasing the final beam current of 5+ and 6+ ion beam by factor of two. Such an increase in efficiency is evident, when utilizing argon in the stripper for 6+ ions, an approximately 8% conversion is achieved, while utilizing SF₆ provides an approximately 16% conversion, or approximately double the amount of the 6+ beam.

While various gases have been conventionally used to strip electrons in an ion beam, sulfur hexafluoride has not been known to be used in a gas stripper in accordance with the present disclosure. A gas stripper operates by passing ions through a material, whereby if the ions are passed through the material at a fast enough speed, an interaction with the background gas or solid film atoms in the stripper causes the ion beam to tend to lose electrons. As such, the ion beam emerges from the stripper at a higher charge, depending on how fast the ions enter the stripper. While ions pass through a stripper utilizing a very thin carbon film will tend to have a higher population of higher charged ions, carbon film tend to have short lifetime and ultimately burn out at a substantially rapid rate.

Because of the limited lifetime of the carbon film stripper, the present disclosure provides a gas as a suitable medium for the stripper. In general terms, a tube is provided within the stripper, whereby a stripping gas is fed to the center of the tube, wherein the gas has a higher gas density than the surrounding vacuum. At ends of the tube, a vacuum is provided (e.g., by a vacuum pump), such that the minimum amount of stripping gas propagates to the rest of the system. As such, a higher pressure region is provided within the stripper, whereby the accelerated ions, such as arsenic ions, pass through the higher pressure region and interact with the stripping gas atoms, thus stripping charge from the ions and producing a higher charge of ions emanating from the stripper. Such higher-charged ions are also advantageously utilized in a tandem accelerator.

The present disclosure appreciates that argon has a molecular weight of approximately 40, while SF₆ is substantially heavier with a molecular weight of approximately 146. As such, one theory posited by the present disclosure is that SF₆ being not only one of the heavier gas molecules, but SF₆ is a highly electronegative molecule that helps the efficiency of stripping electrons from the ion beam. SF₆ is one of the heavier gas molecules more readily available for commercial use, and is thus considered advantageous over other heavier gases. However, the present disclosure contemplates the utilization of other heavy molecular weight gases (e.g., heavier than argon) as having relative electron stripping capabilities. The present disclosure further appreciates that SF₆ is gas that is efficient at suppressing high voltage arc. As such, SF₆ gas is conventionally used in power stations for switches, high voltage transmission lines, in the pressurized tanks of high voltage accelerators, within resonators of an RF accelerator, etc. for suppressing arcs. However, never before has SF₆ been utilized for stripping electrons in the manner described herein.

Heretofore, SF₆ would not have been considered a desirable gas to use in a gas stripper or elsewhere in the beamline. For example, SF₆ is environmentally toxic, and would be concerning if the gas were to be pumped out to atmosphere, or otherwise escape containment within the gas stripper. The present disclosure thus further contemplates breaking down SF₆ into its less toxic and/or less volatile constituents. Alternatively, the SF₆ could be recycled and used again.

Accordingly, the present disclosure inventively contemplates using SF₆ in the beamline as a charge stripper. The inventor appreciates that the conventional use of SF₆ has been to suppress arcs outside of the beamline in a tank for high voltage insulation, whereas the present disclosure utilizes SF₆ within the beamline to strip electrons, wherein the beamline provides a significantly different environment and application than previous uses of SF₆. Conventionally, one of ordinary skill would not have been motived to use of SF₆ in high voltage regions in the vacuum of the beamline, as doing so could make holding of voltages difficult. For example, the present disclosure appreciates that when SF₆ is provided in a vacuum, it tends to induce a spark, thus making its use in the gas stripper counterintuitive, as one of ordinary skill would not desire the presence of SF₆ in the beamline, as it would be assumed to cause deleterious arcing or sparking. The present disclosure, however, yields unexpected results.

The present disclosure further appreciates that SF₆ advantageously provides an additional benefit in the gas stripper, as SF₆ is a heavier gas than the argon gas used in conventional gas strippers, whereby the SF₆ advantageously aids in localizing the high pressure region due to lower conductance through a tube, which is inversely proportional to square root of the molecular weight of the gas. For example, the present disclosure contemplates feeding SF₆ to the middle of a tube of the gas stripper to create a localized high pressure region. If a lighter gas such as hydrogen were to be used in the gas stripper, it would quickly diffuse and be difficult to localize.

According to one or more embodiments, a system and method increase beam current available at a maximum kinetic energy for a charge state without using a higher or different charge state at an ion source. For example, an ion source of an ion implantation system can comprise ions (e.g., arsenic ions) of a particular charge state (e.g., 3+ As) for generating an ion beam therefrom. Processes within the ion implantation system (such as within an accelerator located along a beam path) can act to cause ions to change their initial charge value (e.g., a charge exchange reaction). For example, in one embodiment, an arsenic ion comprising a net positive charge of three can be selected into the accelerator and stripped of electrons by a charge stripper comprising a gas source and a turbo pump. The gas source, in accordance with the present disclosure, comprises a high molecular weight gas, such as sulfur hexafluoride (SF₆).

In one embodiment, the accelerator can comprise a number of accelerator stages and a charge stripper therein. When a high speed ion comes in close proximity to another molecule or atom of a gas within the charge stripper, the ion may pick up an electron from the molecule or atom (i.e., an electron capture reaction), or may lose an electron to the molecule or atom (i.e., a charge stripping reaction). The former reaction reduces the value of ion charge by one; for example, a singly charged ion can become a neutral, that is, an electrically neutral atom. The latter increases the value of ion charge by one (e.g., a singly charged ion becomes a doubly charged ion).

In one embodiment, positive ions (e.g., arsenic ions) comprising a first positive charge state (e.g., +3 net positive charge or valence) are drawn into an accelerator comprising a charge stripper and a plurality of acceleration stages. The respective acceleration stages may comprise RF resonators for generating RF accelerating fields to accelerate ions along a beam path. The charge stripper can comprise a gas source for emitting a high molecular weight gas (e.g., SF₆) into the accelerator and a turbo pump for creating a vacuum to exit the gas and prevent gas flow into acceleration stages. The charge stripper can replace one of the acceleration stages within the accelerator in order to strip ions of an electron, and thus, cause the positive ions entering the accelerator to convert to positive ions of a second charge state (e.g., +6 net positive charge or valence) exiting the accelerator.

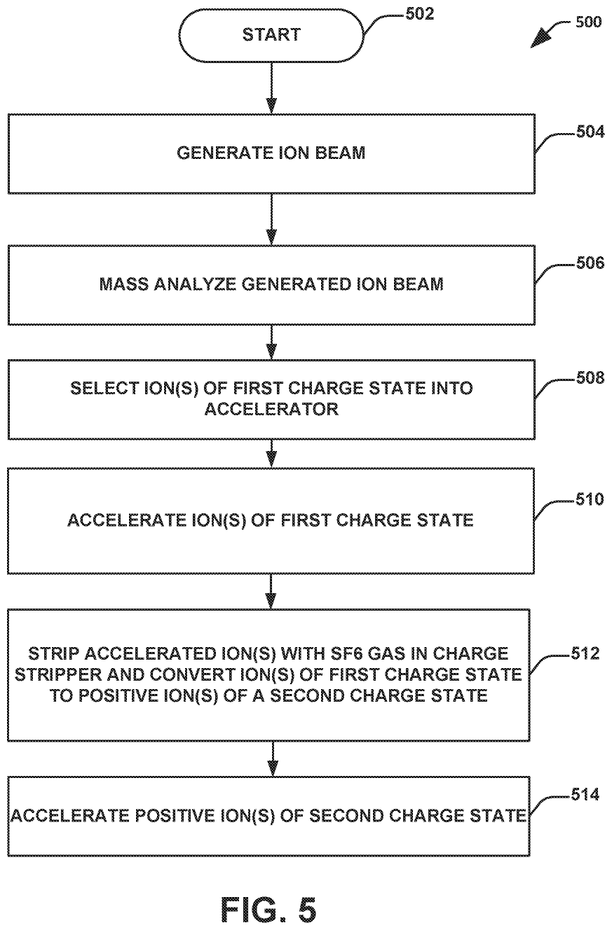

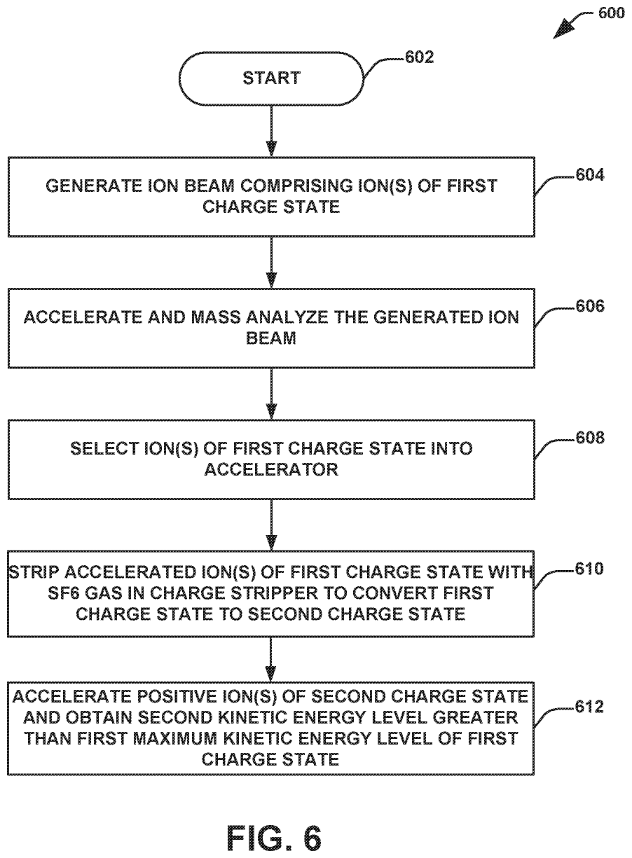

Referring now to FIG. 5 and FIG. 6 it should also be noted that while an exemplary method(s) 500 and 600 are illustrated and described herein as a series of acts or events, it will be appreciated that the present disclosure is not limited by the illustrated ordering of such acts or events, as some steps may occur in different orders and/or concurrently with other steps apart from that shown and described herein, in accordance with the disclosure. In addition, not all illustrated steps may be required to implement a methodology in accordance with the present disclosure. Moreover, it will be appreciated that the methods may be implemented in association with the system 100 and 200 illustrated and described herein as well as in association with other systems not illustrated.

The method 500 of FIG. 5 initiates at 502. An ion source generates an ion beam 504 and directs the beam into a mass analyzer. At 506 the ion beam generated is mass analyzed. The magnetic field strength for the mass analyzer can be selected according to a charge-to-mass ratio. The mass analyzing can be downstream of the ion source, in one example.

In one example, ion(s) of first positive or negative charge state(s) can be selected 508 (e.g., via the mass analyzer) to enter into an accelerator. At 510 the selected ion(s) of first charge state(s) are accelerated to an energy, which yields a higher stripping efficiency to a higher charge state than available at ion source. The accelerated ion(s) of first charge state(s) enter a stripping canal of a charge stripper comprising SF₆, for example, and at 512 these ions are stripped and converted to positives ion(s) of second positive charge state(s). Positive ion(s) of second positive charge state(s) are accelerated at 514.

The method 600 of FIG. 6 initiates at 602. An ion source generates an ion beam comprising positive or negative ions of a first charge state (e.g., As 3+ or As−). The ion beam can be of various beam species (e.g., Arsenic). At 606 the generated ion beam can be accelerated and mass analyzed in no specific order. At 608 ions comprising the first charge stated can be selected into an accelerator. At 610 the ions may be further accelerated and stripped of electrons by passing the ion beam through a high molecular weight gas, such as SF₆, to convert them to positive ions of a second positive charge state (e.g., As 6+). At 612 positive ions of the second positive charge state can be accelerated, and a second kinetic energy level greater than a first maximum kinetic energy level of the first positive charge state can be obtained.

Although the disclosure has been shown and described with respect to a certain applications and implementations, it will be appreciated that equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure, which performs the function in the herein illustrated exemplary implementations of the disclosure.

In addition, while a particular feature of the disclosure may have been disclosed with respect to only one of several implementations, such feature may be combined with one or more other features of the other implementations as may be desired and advantageous for any given or particular application. Furthermore, to the extent that the terms “includes”, “including”, “has”, “having”, and variants thereof are used in either the detailed description or the claims, these terms are intended to be inclusive in a manner similar to the term “comprising”.

What is claimed is:

1. An ion implantation system, comprising:
an ion source configured to generate an ion beam from a beam species, therein defining a generated ion beam;
a mass analyzer configured to mass analyze the generated ion beam to define an analyzed ion beam, wherein the analyzed ion beam comprises ions at a first charge state;
an accelerator configured to receive the analyzed ion beam, wherein the accelerator is configured to define an exited ion beam, wherein the accelerator comprises:
a charge stripper configured to receive the ions at the first charge state and to convert the ions at the first charge state to the ions at a second charge state, wherein the second charge state is a more positive charge state than the first charge state;
a gas source configured to provide a gas to the charge stripper, wherein the gas is configured to strip electrons from the ions at the first charge state; and
a plurality of accelerator stages respectively configured to accelerate the ions therein; and
an end station positioned downstream of the accelerator and configured to support a workpiece for implantation thereto of the ions at the second charge state.

2. The ion implantation system of claim 1, wherein the gas comprises a high molecular weight gas.

3. The ion implantation system of claim 2, wherein the high molecular weight gas comprises sulfur hexafluoride gas.

4. The ion implantation system of claim 1, wherein the beam species comprises one or more of boron, phosphorus, and arsenic.

5. The ion implantation system of claim 1, wherein the charge stripper is configured to provide more ions at the second charge state than are present in the generated ion beam and to increase a beam current of the exited ion beam, and wherein the charge stripper is positioned downstream of at least a first of the plurality of accelerator stages and upstream of at least a second of the plurality of accelerator stages.

6. The ion implantation system of claim 1, wherein the second charge state has a net charge that is greater than the first charge state by at least one.

7. The ion implantation system of claim 1, wherein the first charge state comprises a net charge of +3, the second charge state comprises a net charge of +6, and wherein the gas comprises sulfur hexafluoride.

8. The ion implantation system of claim 1, wherein the first charge state comprises a net charge of −1, the second charge state comprises a net charge of at least +1, and wherein the gas comprises sulfur hexafluoride.

9. A method for operating a high energy ion implanter, the method comprising:
generating ions of a beam species from an ion source, thereby defining a ion beam;
mass analyzing the ion beam;
selecting ions of a first charge state into an accelerator;
accelerating the ions of the first charge state through at least one of a first plurality of accelerator stages located within the accelerator, thereby defining accelerated ions at a first kinetic energy level;
stripping the accelerated ions with a charge stripper comprising sulfur hexafluoride gas located within the accelerator, thereby converting the ions of the first charge state to positive ions of a second charge state, wherein the first charge state is different from the second charge state; and
accelerating the ions of the second charge state through at least one of a second plurality of accelerator stages located within the accelerator.

10. The method of claim 9, wherein stripping the accelerated ions is performed with a stripping efficiency that is based on the first kinetic energy level, wherein the stripping provides more ions of the second charge state than are present at the ion source, and wherein a beam current of the accelerated ions is increased at a second kinetic energy that is greater than the first kinetic energy level.

11. The method of claim 9, wherein stripping the accelerated ions comprises supplying the sulfur hexafluoride gas within the charge stripper, thereby stripping an electron from respective ions of the first charge state to convert the ions of the first charge state to ions of the second charge state, and further comprising adjusting a flow rate of the sulfur hexafluoride gas into the charge stripper based on at least one of an energy, a current and/or the beam species of the ion beam.

12. The method of claim 9, wherein one or more of the first plurality of accelerator stages and the second plurality of accelerator stages respectively comprise at least one resonator, whereby the resonator generates an RF accelerating field to accelerate ions therein.

13. The method of claim 9, wherein the second charge state is more positive than the first charge state.

14. The method of claim 9, wherein the first plurality of accelerator stages and second plurality of accelerator stages comprise at least ten accelerator stages and at least one resonator.

15. The method of claim 9, wherein the second charge state increases a net charge of the first charge state by at least one.

16. The method of claim 9, wherein the first charge state comprises a net charge of +3 and the second charge state comprises a net charge of +6.

17. The method of claim 9, wherein the first charge state comprises a net charge of −1 and the second charge state comprises a net charge of +1 or greater.

18. The method of claim 9, wherein the charge stripper is positioned downstream of at least one of the first plurality of accelerator stages and upstream of at least one of the second plurality of accelerator stages.

19. The method of claim 9, wherein a quantity of the first plurality of accelerator stages is less than or equal a quantity of the second plurality of accelerator stages.

20. The method of claim 9, wherein a quantity of the first plurality of accelerator stages is greater than a quantity of the second plurality of accelerator stages.

21. The method of claim 9, wherein stripping the accelerated ions is performed at two or more accelerator stages selected from the first plurality of accelerator stages and second plurality of accelerator stages.

22. A method of increasing beam current of a high energy ion implanter to above a first maximum kinetic energy level of a first charge state without using a second different charge state at an ion source, the method comprising:
generating an ion beam comprising ions of the first charge state and a beam species from the ion source;
mass analyzing the ion beam;
accelerating the ions of the first charge state to a first kinetic energy through at least one of a plurality of accelerator stages;
stripping the ions of the first charge state with a charge stripper utilizing a high molecular weight gas, thereby converting the ions of the first charge state to ions of a second charge state, wherein the stripping is performed with a stripping efficiency that is based on the first kinetic energy and provides more positive ions of the second charge state than at the ion source and increases a beam current at a second kinetic energy that is higher than the first kinetic energy associated with the ions of the first charge state.

23. The method of claim 22, wherein the high molecular weight gas comprises sulfur hexafluoride.

24. The method of claim 22, wherein the second charge state more positive than the first charge state, and wherein the beam species comprises boron and/or phosphorus.

25. The method of claim 22, wherein the second charge state increases a net charge of the first charge state by at least one.

26. The method of claim 22, wherein the first charge state comprises a net charge of +3 and the second charge state comprises a net charge of +6.
